(19) United States
(12) Patent Application Publication
(10) Pub. No.: US 2011/0000533 A1
(43) Pub. Date: Jan. 6, 2011

(54) PHOTOELECTRIC CONVERSION ELEMENT STRUCTURE AND SOLAR CELL

(75) Inventors: Tadahiro Ohmi, Miyagi (JP); Tetsuya Goto, Miyagi (JP); Kouji Tanaka, Miyagi (JP); Yuichi Sano, Osaka (JP)

Correspondence Address: PEARNE & GORDON LLP, 1801 EAST 9TH STREET, SUITE 1200, CLEVELAND, OH, 44114-3108, US

(73) Assignees: NATIONAL UNIVERSITY CORPORATION TOHOKU UNIVERSITY, Sendai-shi, Miyagi (JP); TOKYO ELECTRON LIMITED, Tokyo (JP)

(21) Appl. No.: 12/920,900

(22) PCT Filed: Mar. 2, 2009
(86) PCT No.: PCT/JP2009/053814

§ 371 Date: Sep. 3, 2010

(30) Foreign Application Priority Data
Mar. 7, 2008 (JP) 2008-057314

(51) Int. Cl. H01L 31/105

(52) U.S. Cl. 136/255; 257/458; 257/E31.061

(57) ABSTRACT

It is possible to reduce the contact resistance so as to improve the conversion efficiency of a photoelectric conversion element structure. Provided is a photoelectric conversion element structure of the pin structure which selects an upper limit energy level of the valence band of the p-type semiconductor or the electron affinity of the n-type semiconductor layer and the work function of a metal layer which is brought into contact with the semiconductor, so as to reduce the contact resistance as compared to the case when Al or Ag is used as an electrode. The selected metal layer may be arranged between the electrode formed from Al or Ag and the semiconductor or may be substituted for the n- or p-type semiconductor.

### TECHNICAL FIELD

This invention relates to a photoelectric conversion element structure and a solar cell including the photoelectric conversion element structure.

### BACKGROUND ART

In hitherto proposed solar cells, there is a solar cell including a photoelectric conversion element structure formed by thin films. In this case, there may be employed a pin structure including a structure in which a one conductivity-type (e.g. p-type) semiconductor layer and an opposite conductivity-type (e.g. n-type) semiconductor layer are in contact with both surfaces of an i-type semiconductor layer, respectively. When such a pin structure is employed, it is possible to increase the carrier diffusion length by applying an electric field to the i-type semiconductor layer. It is proposed to form respective semiconductor layers in photoelectric conversion element structures of various semiconductors such as amorphous semiconductor, microcrystalline semiconductor, single-crystalline semiconductor, and polycrystalline semiconductor. Further, it is also proposed to use Si, SiC, Ge, SiGe, and so on as semiconductors forming respective semiconductor layers.

As described above, since it is necessary to form three kinds of semiconductor layers different from each other for the solar cell including the photoelectric conversion element structure of the three-layer structure including the i-layer, the situation is such that an increase in cost cannot be avoided.

Patent Documents 1 and 2 each disclose a thin-film solar cell including a pin-type photoelectric conversion element structure. Specifically, the thin-film solar cell described in Patent Document 1 has a pin-type amorphous photoelectric conversion element structure with a layer of amorphous silicon containing a microcrystalline phase (μc-Si). That is, the thin-film solar cell described in Patent Document 1 has pin layers forming a power generating layer in which the p-layer is formed by a semiconductor layer containing a microcrystalline phase (μc-Si), the i-layer is formed of amorphous silicon germanium (a-SiGe), and a p-type low impurity concentration interface layer with a band gap larger than that of the p-layer is provided between the p-layer and the i-layer. This photoelectric conversion element structure is capable of suppressing degradation of properties after light irradiation and improving the efficiency.

Patent Document 2 discloses the solar cell including a photoelectric conversion element structure with high conversion efficiency by suppressing degradation of interface properties due to thermal diffusion in a manufacturing process. Patent Document 2 proposes a photoelectric conversion element structure having pin layers forming a power generating layer in which the p-type and n-type semiconductor layers are respectively formed by amorphous silicon-based thin films each including a microcrystalline phase (μc-Si) and the i-type semiconductor layer is formed by an amorphous silicon-based film. Further, Patent Document 2 proposes a structure in which an interface semiconductor layer in the form of a plurality of layers is provided between the p-type or n-type semiconductor layer and the i-type semiconductor layer. Herein, the impurity addition amount in the interface semiconductor layer on the i-type semiconductor layer side is set smaller than that in the interface semiconductor layer on the amorphous semiconductor layer side, thereby causing a band gap at the junction interface, on the p-type semiconductor layer side, of the i-type semiconductor layer to be larger than that of the i-type semiconductor layer. The solar cell including the above-mentioned photoelectric conversion element structure can suppress degradation of interface properties.

Patent Document 1: JP-A-2001-168354

Patent Document 2: JP-A-2003-8038

### DISCLOSURE OF THE INVENTION

### Problem to be Solved by the Invention

As described above, Patent Documents 1 and 2 each aim to improve the conversion efficiency by changing the internal structure of the power generating layer, comprising the pin three layers, to suppress the degradation of interface properties.

That is, Patent Document 1 shows the structure in which the interface layer is provided between the p-layer and the i-layer and Patent Document 2 also shows the structure in which the interface semiconductor layer is provided between the i-type semiconductor layer and the p-type or n-type semiconductor layer. In other words, neither of Patent Documents 1 and 2 points out a problem caused by contact resistances due to electrode layers formed in contact with the pin layers.

It is an object of this invention to provide a photoelectric conversion element structure and a solar cell which can reduce the contact resistance between an electrode layer and a semiconductor layer.

It is another object of this invention to provide a photoelectric conversion element structure and a solar cell which are high in conversion efficiency and highly economical, by improving an electrode layer formed in contact with a power generating layer.

It is still another object of this invention to provide a photoelectric conversion element structure and a solar cell which are reduced in contact resistance by improving the structure of a power generating layer itself.

### Means for Solving the Problem

According to a first aspect of this invention, there is provided a photoelectric conversion element structure characterized by comprising a first electrode layer, a second electrode layer, and one or a plurality of power generating laminates provided between the first and second electrode layers, wherein the power generating laminate comprises a p-type semiconductor layer, an i-type semiconductor layer formed in contact with the p-type semiconductor layer, and an n-type semiconductor layer formed in contact with the i-type semiconductor layer, the p-type semiconductor layer of the one power generating laminate or of the power generating laminate, on the first electrode side, of the plurality of power generating laminates is in contact with the first electrode layer and the n-type semiconductor layer of the one power generating laminate or of the power generating laminate, on the first electrode side, of the plurality of power generating laminates is in contact with the second electrode layer, and at least a portion, being in contact with the n-type semiconductor layer, of the second electrode layer comprises a metal having a work function which is smaller in absolute value than an electron affinity of the contacting n-type semiconductor layer (4.09 eV in absolute value in the case of n-type silicon).

According to a second aspect of this invention, there is provided the photoelectric conversion element structure, characterized in that the at least a portion, being in contact with the n-type semiconductor layer, of the second electrode layer is formed of at least one kind of elementary metal selected from the group comprising magnesium, hafnium, and yttrium, or an alloy thereof.

According to a third aspect of this invention, there is provided the photoelectric conversion element structure in any one of the above-mentioned aspects, characterized in that the i-type semiconductor layer in at least one of the power generating laminates is formed of any of crystalline silicon, microcrystalline amorphous silicon, and amorphous silicon.

According to a fourth aspect of this invention, there is provided the photoelectric conversion element structure in any one of the above-mentioned aspects, characterized in that the second electrode layer is formed of the metal having the work function which is smaller in absolute value than the electron affinity of the contacting n-type semiconductor layer.

According to a fifth aspect of this invention, there is provided the photoelectric conversion element in any one of the above-mentioned aspects, characterized in that a portion, other than the portion being in contact with the n-type semiconductor layer, of the second electrode layer is formed of a metal with a conductivity higher than that of the metal having the work function which is smaller in absolute value than the electron affinity of the contacting n-type semiconductor layer.

According to a sixth aspect of this invention, there is provided the photoelectric conversion element structure in any one of the above-mentioned aspects, characterized in that at least a portion, being in contact with the p-type semiconductor layer, of the first electrode layer comprises a metal having a work function which is larger in absolute value than an upper limit energy level of a valence band of the contacting p-type semiconductor layer (5.17 eV in absolute value in the case of p-type silicon).

According to a seventh aspect of this invention, there is provided a photoelectric conversion element structure characterized by comprising a first electrode layer, a second electrode layer, and one or a plurality of power generating laminates provided between the first and second electrode layers, wherein the power generating laminate comprises a p-type semiconductor layer, an i-type semiconductor layer formed in contact with the p-type semiconductor layer, and an n-type semiconductor layer formed in contact with the i-type semiconductor layer, the p-type semiconductor layer of the one power generating laminate or of the power generating laminate, on the first electrode side, of the plurality of power generating laminates is in contact with the first electrode layer and the n-type semiconductor layer of the one power generating laminate or of the power generating laminate, on the first electrode side, of the plurality of power generating laminates is in contact with the second electrode layer, and at least a portion, being in contact with the p-type semiconductor layer, of the first electrode layer comprises a metal having a work function which is larger in absolute value than an upper limit energy level of a valence band of the contacting p-type semiconductor layer.

According to an eighth aspect of this invention, there is provided the photoelectric conversion element structure, characterized in that the at least a portion, being in contact with the p-type semiconductor layer, of the first electrode layer is formed of at least one kind of elementary metal selected from the group comprising nickel (Ni), iridium (Ir), palladium (Pd), and platinum (Pt), or an alloy thereof.

According to a ninth aspect of this invention, there is provided the photoelectric conversion element structure, characterized in that the first electrode layer is formed of the metal having the work function which is larger in absolute value than the upper limit energy level of the valence band of the contacting p-type semiconductor layer.

According to a tenth aspect of this invention, there is provided the photoelectric conversion element structure, characterized in that a portion, other than the portion being in contact with the p-type semiconductor layer, of the first electrode layer is formed of a metal with a conductivity higher than that of the metal having the work function which is larger in absolute value than the upper limit energy level of the valence band of the contacting p-type semiconductor layer.

According to an eleventh aspect of this invention, there is provided a photoelectric conversion element structure, characterized by comprising an i-type semiconductor layer, a one conductivity-type semiconductor layer formed in contact with one surface of the i-type semiconductor layer, and a metal layer comprising a predetermined metal and formed in direct contact with another surface of the i-type semiconductor layer.

According to a twelfth aspect of this invention, there is provided the photoelectric conversion element structure, characterized in that the metal layer, along with the i-type semiconductor layer and the one conductivity-type semiconductor layer, forms a power generating region.

According to a thirteenth aspect of this invention, there is provided the photoelectric conversion element structure, characterized by comprising an electrode formed in contact with the one conductivity-type semiconductor layer directly or through another power generating region.

According to a fourteenth aspect of this invention, there is provided the photoelectric conversion element structure, characterized by comprising another electrode layer formed in contact with the metal layer.

According to a fifteenth aspect of this invention, there is provided the photoelectric conversion element structure, characterized in that the one conductivity-type semiconductor layer formed in contact with the one surface of the i-type semiconductor layer is a p-type semiconductor layer.

According to a sixteenth aspect of this invention, there is provided the photoelectric conversion element structure in any one of the eleventh to the fifteenth aspects, characterized in that when a semiconductor forming the i-type semiconductor layer is an n-type semiconductor, the metal of the metal layer formed in contact with the another surface of the i-type semiconductor layer is a metal having a work function which is smaller in absolute value than an electron affinity of the n-type semiconductor.

According to a seventeenth aspect of this invention, there is provided the photoelectric conversion element structure in any one of the eleventh to the fourteenth aspects, characterized in that the one conductivity-type semiconductor layer formed in contact with the one surface of the i-type semiconductor layer is an n-type semiconductor layer and, when a semiconductor forming the i-type semiconductor layer is a p-type semiconductor, the metal of the metal layer formed in contact with the another surface of the i-type semiconductor layer is a metal having a work function which is larger in absolute value than an upper limit energy level of a valence band of the p-type semiconductor.

According to an eighteenth aspect of this invention, there is provided a photoelectric conversion element structure characterized by comprising a first electrode layer, a second electrode layer, and one or a plurality of power generating laminates provided between the first and second electrode layers, wherein the power generating laminate comprises a p-type semiconductor layer, an i-type semiconductor layer formed in contact with the p-type semiconductor layer, and an n-type semiconductor layer formed in contact with the i-type semiconductor layer, the p-type semiconductor layer of the one power generating laminate or of the power generating laminate, on the first electrode side, of the plurality of power generating laminates is in contact with the first electrode layer and the n-type semiconductor layer of the one power generating laminate or of the power generating laminate, on the first electrode side, of the plurality of power generating laminates is in contact with the second electrode layer, and at least a portion, being in contact with the n-type semiconductor layer, of the second electrode layer comprises a metal having a work function which is smaller in absolute value than those of Al and Ag.

According to a nineteenth aspect of this invention, there is provided the photoelectric conversion element structure in the eighteenth aspect, characterized in that the at least a portion, being in contact with the n-type semiconductor layer, of the second electrode layer is formed of at least one kind of elementary metal selected from the group comprising manganese and zirconium, or an alloy thereof.

According to a twentieth aspect of this invention, there is provided a photoelectric conversion element structure characterized by comprising a first electrode layer, a second electrode layer, and one or a plurality of power generating laminates provided between the first and second electrode layers, wherein the power generating laminate comprises a p-type semiconductor layer, an i-type semiconductor layer formed in contact with the p-type semiconductor layer, and an n-type semiconductor layer formed in contact with the i-type semiconductor layer, the p-type semiconductor layer of the one power generating laminate or of the power generating laminate, on the first electrode side, of the plurality of power generating laminates is in contact with the first electrode layer and the n-type semiconductor layer of the one power generating laminate or of the power generating laminate, on the first electrode side, of the plurality of power generating laminates is in contact with the second electrode layer, and at least a portion, being in contact with the p-type semiconductor layer, of the first electrode layer comprises a metal having a work function which is larger in absolute value than that of ZnO.

According to a twenty-first aspect of this invention, there is provided the photoelectric conversion element structure in the twentieth aspect, characterized in that the at least a portion, being in contact with the n-type semiconductor layer, of the second electrode layer is formed of at least one kind of elementary metal selected from the group comprising manganese and zirconium, or an alloy thereof.

According to a twenty-second aspect of this invention, there is provided the photoelectric conversion element structure in any one of the eleventh to the twenty-first aspects, characterized in that the i-type semiconductor layer is formed of silicon.

According to a twenty-third aspect of this invention, there is provided a solar cell characterized by comprising the photoelectric conversion element structure in any one of the eleventh to the twenty-second aspects.

### EFFECT OF THE INVENTION

According to this invention, a photoelectric conversion element structure with high conversion efficiency is obtained by reducing the contact resistance between an electrode layer and a semiconductor layer.

### BRIEF DESCRIPTION OF THE DRAWINGS

FIG. 1 is a diagram showing an equivalent circuit of a photoelectric conversion element structure for explaining the principle of this invention.

FIG. 2 is a schematic diagram for explaining a photoelectric conversion element structure according to one embodiment of this invention.

FIG. 3A is a diagram showing band structures before and after contact between n-Si and a metal when the work functions thereof are in a relationship of φs<φm.

FIG. 3B is a diagram showing band structures before and after contact between n-Si and a metal when the work functions thereof are in a relationship of φs<φm.

FIG. 4A is a diagram showing band structures before and after contact between n-Si and a metal when the work functions thereof are in a relationship of φs>φm.

FIG. 4B is a diagram showing band structures before and after contact between n-Si and a metal when the work functions thereof are in a relationship of φs>φm.

FIG. 5 is a schematic diagram for explaining a photoelectric conversion element structure according to another embodiment of this invention.

FIG. 6 is a schematic diagram for explaining a photoelectric conversion element structure according to still another embodiment of this invention.

### DESCRIPTION OF SYMBOLS

10 power generating layer (cell portion)
21 first electrode
22 second electrode
25 power generating layer
251 p-type semiconductor layer
252 n-type semiconductor layer
253 i-type semiconductor layer
30 additional electrode layer
35 metal layer

### BEST MODE FOR CARRYING OUT THE INVENTION

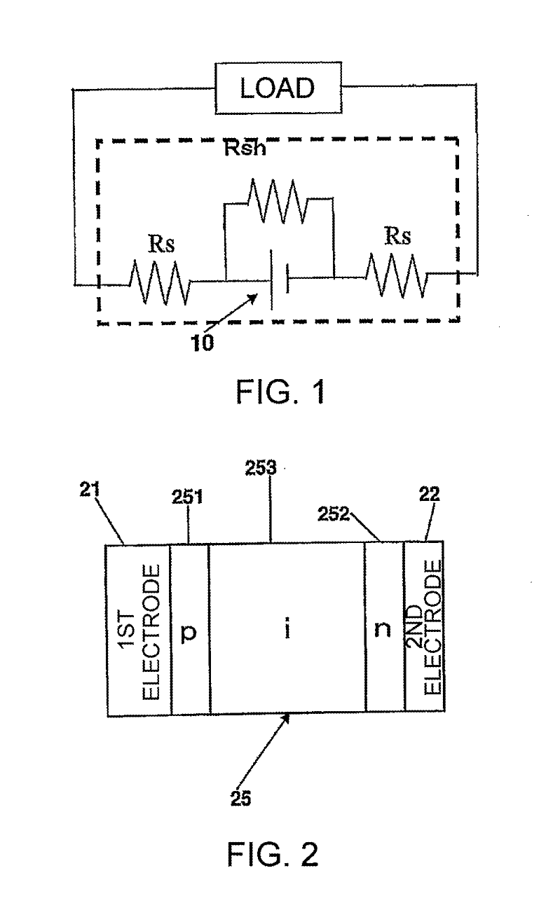

Referring to an equivalent circuit diagram of a photoelectric conversion element shown in FIG. 1, the principle of this invention will be described. As illustrated, the photoelectric conversion element structure forming a solar cell can be equivalently expressed by a power generating layer (i.e. a cell portion) 10 adapted to generate electricity by irradiation of light, a parallel resistance Rsh corresponding to a leakage current that flows due to junction interface mismatching in the power generating layer 10, and resistances Rs between two electrodes and the power generating layer 10 interposed therebetween. Herein, the resistance Rs is a combined resistance of a resistance of each electrode itself and a contact resistance between each electrode and a semiconductor layer forming the power generating layer. As is also clear from the figure, a load is connected between the two resistances Rs.

The principle of this invention is to improve the conversion efficiency of the photoelectric conversion element structure by reducing the contact resistances of the resistances Rs in the equivalent circuit shown in FIG. 1.

Referring to FIG. 2, a photoelectric conversion element structure according to a first embodiment of this invention comprises, as shown in FIG. 2, a first electrode 21 in the form of a transparent electrode, a second electrode 22 with a high reflectance like Al or Ag, and a power generating layer 25 composed of three layers, i.e. pin layers, provided between the first and second electrodes 21 and 22. The power generating layer 25 comprises a p-type semiconductor layer 251 formed in contact with the first electrode 21, an n-type semiconductor layer 252 formed in contact with the second electrode 22, and an i-type semiconductor layer 253 provided between the p-type semiconductor layer 251 and the n-type semiconductor layer 252. In this embodiment, crystalline silicon (Si) is used as the p-type semiconductor layer 251, the i-type semiconductor layer 253, and the n-type semiconductor layer 252 forming the power generating layer 25. In this case, the upper limit energy level of a valence band of p-Si formed of crystalline silicon is −5.17 eV and a metal having a work function larger in absolute value than that is used as the first electrode 21. Alternatively, a metal or its alloy having a work function larger in absolute value than that of ZnO is used as the first electrode 21.

On the other hand, the electron affinity of n-Si is −4.09 eV and a metal having a work function smaller in absolute value than that is used as the second electrode 22. Alternatively, a metal or its alloy having a work function smaller in absolute value than those of Al and Ag is used as the second electrode 22.

In the first embodiment of this invention, attention has been paid to the work function of the back electrode, i.e. the second electrode 22, thus reducing the contact resistance between the second electrode 22 and the n-type semiconductor layer 252. In general, aluminum (Al) having a work function of −4.28 eV or silver (Ag) having a work function of −4.26 eV is used as the second electrode 22.

Herein, the second electrode 22 is formed of a metal material having a work function smaller in absolute value than the electron affinity −4.09 eV of the semiconductor (n-Si) and preferably having a high reflectance. Specifically, by forming the second electrode 22 of the metal material adapted to form an ohmic contact with the semiconductor made of n-Si, the contact resistance can be reduced as compared with Al or Ag.

Alternatively, even by using a metal material adapted to form a Schottky barrier with the semiconductor made of n-Si, the contact resistance can be reduced as compared with Al or Ag.

The above-mentioned metal material capable of reducing the contact resistance can be determined taking into account the work function thereof with respect to n-Si. Hereinafter, the work function of a metal material will be given by φm and the electron affinity of a semiconductor (herein n-Si) will be given by φs.

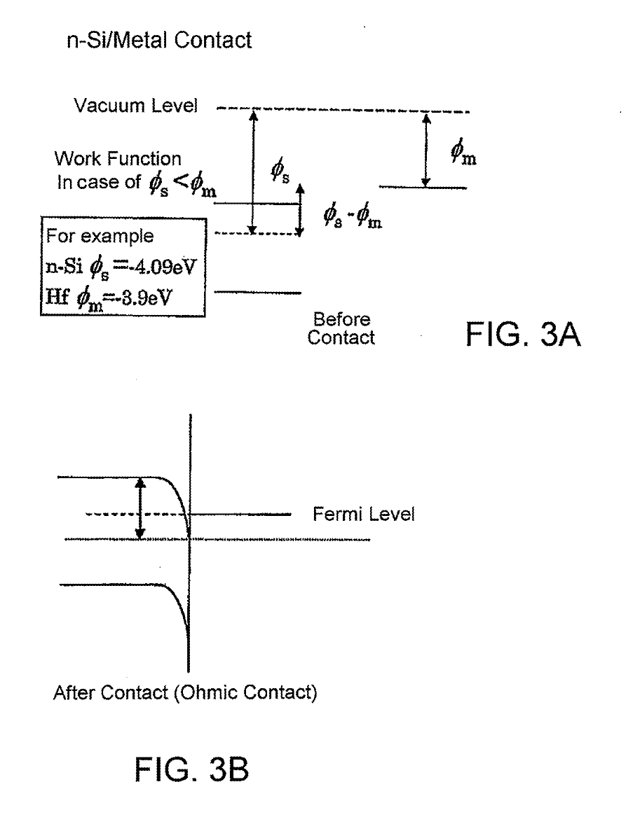

Now, referring to FIGS. 3A and 3B, there are shown a state before contact and a state after contact when the relationship between work functions with respect to the vacuum level is φm<φs in absolute value. When such a semiconductor and such a metal are brought into contact with each other, an ohmic contact is formed as shown in FIG. 3B. Since φs of n-Si is −4.09 eV as described above, Mg with a work function of −3.7 eV, Hf with a work function of −3.9, Y with a work function of −3.1 eV, or the like can be used as a metal material with a work function φm which is smaller in absolute value than the work function of n-Si. By using such a metal, it is possible to reduce the contact resistance as compared with the case where Al or Ag is brought into contact with n-Si.

On the other hand, even by using a metal having a work function smaller in absolute value than those of Al and Ag, it is possible to reduce the contact resistance as compared with the case where Al or Ag is brought into contact with n-Si.

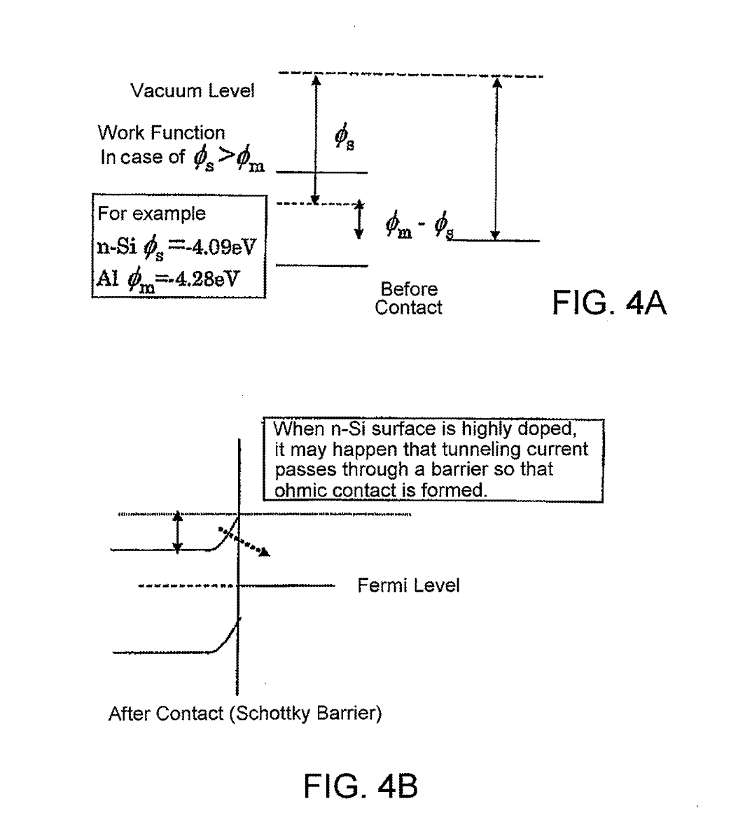

For example, Mn or Zr having a work function of −4.1 eV is, like Al with −4.28 eV and Ag with −4.26 eV, slightly smaller in work function than n-Si having the work function of −4.09 eV and thus the work functions thereof are in a relationship of φs<φm. In this case, a state before such a metal material is brought into contact with n-Si is as shown in FIG. 4A while, when both are brought into contact with each other, a Schottky barrier is formed as shown in FIG. 4B. However, when a surface of n-Si is highly doped, a tunneling current passes through the barrier so that an ohmic contact is formed, which is similar to Al or Ag.

Since the work function of Mn or Zr is closer than those of Al and Ag to the work function φs of n-Si and is smaller in absolute value than those of Al and Ag, even if the second electrode 22 is formed of Mn or Zr, it is possible to reduce the contact resistance as compared with the case of using Al or Ag.

In fact, the contact resistance between Al and n-Si is about 5×10-6 Ω·cm2 while, in the case of Mn or Zr where the difference between the work function φm of the metal and the work function φs of n-Si is 0.05 eV, it is possible to achieve a contact resistance of about 5×10-12 Ω·cm2. Further, also in the case of another metal such as Mg, Hf, or Y, it is possible to reduce the contact resistance to about 10-8 Ω·cm2.

In the above-mentioned example, consideration has been given to the contact resistance between the second electrode 22 and n-Si shown in FIG. 2. However, also with respect to the first electrode 21 and p-Si 251, it is possible to reduce the contact resistance between p-Si and the first electrode 21. The upper limit energy level φs of a valence band of p-Si is normally −5.17 eV and a metal having a work function larger in absolute value than that is used as the first electrode 21. For example, when use is made of a metal having a work function φm larger in absolute value than the upper limit energy level φs (−5.17 eV) of the valence band of p-Si (i.e. φs<φm), an ohmic contact is formed. Specifically, since the work function φm of Ni is −5.2 eV, when Ni is used as an electrode material, it is possible to reduce the contact resistance with p-Si. Ir, Pd, and Pt are also preferable because their work functions are −5.3 eV, −5.2 eV, and −5.7 eV, respectively.

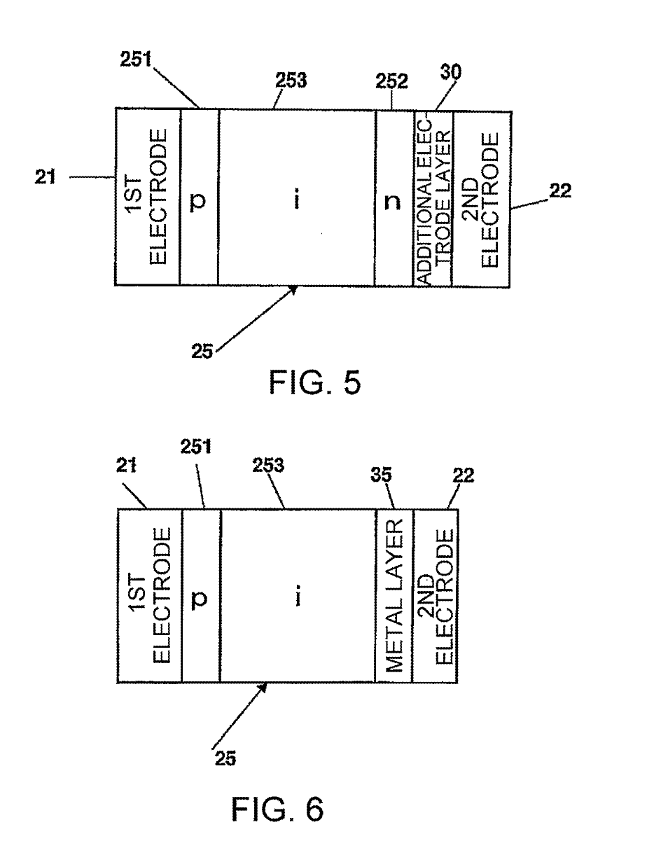

Referring to FIG. 5, a photoelectric conversion element structure according to another embodiment of this invention will be described. The photoelectric conversion element structure shown in FIG. 5 is configured such that an additional metal layer 30 is provided between n-Si 252 and a second electrode 22. Al or Ag is used as the illustrated second electrode 22 as usual to thereby ensure the reflectance at the second electrode 22 while the additional metal layer 30 for reducing the contact resistance is provided between the second electrode 22 and n-Si 252. By selecting, as a metal forming the additional metal layer 30, for example, a metal (Mg, Mn, Hf, Y, Zr, or the like) having a work function smaller in absolute value than the work function φm of Al or Ag forming the second electrode 22, the contact resistance can be reduced. Using such a metal, it is possible to substantially form an ohmic contact with n-Si 252.

In order to reduce the contact resistance between p-Si 251 having a work function of −5.15 eV and a first electrode 21, an additional metal layer may be provided between p-Si 251 and the first electrode 21. When ZnO having a work function of −4.25 eV is used as the electrode on the p-Si side, the contact resistance can be reduced by using, as the additional metal layer, a metal material having a work function larger in absolute value than that of ZnO, such as Co with −5.0 eV or Ni with −5.2 eV.

Referring to FIG. 6, a photoelectric conversion element structure according to still another embodiment of this invention is configured such that n-Si 252 is replaced by a metal layer 35 in the photoelectric conversion element structure shown in FIG. 2, that is, n-Si 252 is omitted. As the metal layer 35, use is made of a metal material having a work function φm which is equivalent to that of n-Si 252. As the metal having the work function φm which is equivalent to that of n-Si 252 having the work function φs of −4.09 eV, it is possible to use Mn or Zr having the work function φm of −4.1 eV.

FIG. 6 shows the example in which n-Si 252 is replaced by the metal layer 35, but p-Si 251 having the work function φs of −5.15 eV may be replaced by a metal layer. In this case, the contact resistance can be reduced by using Co with the work function of −5.0 eV, Ni with −5.2 eV, Pd with −5.2 eV, Ir with −5.3 eV, or the like as a metal material forming the metal layer.

In the above-mentioned embodiments, the description has been given only of the case where crystalline silicon is used. However, this invention is by no means limited thereto and is also similarly applicable to the case where use is made of amorphous silicon or microcrystal-containing amorphous silicon (μc-Si). In this case, it is needless to say that a metal is selected taking into account the work function of amorphous silicon or μc-Si.

Further, this invention is applicable not only to the case where silicon is used, but also to the case where another semiconductor is used, thereby reducing the contact resistance to improve the conversion efficiency.

### INDUSTRIAL APPLICABILITY

A photoelectric conversion element according to this invention is applicable not only to a solar cell, but also to a photoelectric conversion element for another electronic device.

What is claimed is:

1. A photoelectric conversion element structure comprising a first electrode layer, a second electrode layer, and one or a plurality of power generating laminates provided between said first and second electrode layers,
wherein said power generating laminate comprises a p-type semiconductor layer, an i-type semiconductor layer formed in contact with said p-type semiconductor layer, and an n-type semiconductor layer formed in contact with said i-type semiconductor layer,
said p-type semiconductor layer of said one power generating laminate or of the power generating laminate, on the first electrode side, of said plurality of power generating laminates is in contact with said first electrode layer and said n-type semiconductor layer of said one power generating laminate or of the power generating laminate, on the second electrode side, of said plurality of power generating laminates is in contact with said second electrode layer, and
at least a portion, being in contact with said n-type semiconductor layer, of said second electrode layer comprises a metal having a work function which is smaller in absolute value than an electron affinity of said contacting n-type semiconductor layer.

2. A photoelectric conversion element structure according to claim 1, wherein said at least a portion, being in contact with said n-type semiconductor layer, of said second electrode layer is formed of at least one kind of elementary metal selected from the group comprising magnesium, hafnium, and yttrium, or an alloy thereof.

3. A photoelectric conversion element structure according to claim 1, wherein said i-type semiconductor layer in at least one of said power generating laminates is formed of any of crystalline silicon, microcrystalline amorphous silicon, and amorphous silicon.

4. A photoelectric conversion element structure according to claim 1, wherein said second electrode layer is formed of the metal having the work function which is smaller in absolute value than the electron affinity of said contacting n-type semiconductor layer.

5. A photoelectric conversion element structure according to claim 1, wherein a portion, other than said portion being in contact with said n-type semiconductor layer, of said second electrode layer is formed of a metal with a conductivity higher than that of the metal having the work function which is smaller in absolute value than the electron affinity of said contacting n-type semiconductor layer.

6. A photoelectric conversion element structure according to claim 1, wherein at least a portion, being in contact with said p-type semiconductor layer, of said first electrode layer comprises a metal having a work function which is larger in absolute value than an upper limit energy level of a valence band of said contacting p-type semiconductor layer.

7. A photoelectric conversion element structure comprising a first electrode layer, a second electrode layer, and one or a plurality of power generating laminates provided between said first and second electrode layers,
wherein said power generating laminate comprises a p-type semiconductor layer, an i-type semiconductor layer formed in contact with said p-type semiconductor layer, and an n-type semiconductor layer formed in contact with said i-type semiconductor layer,
said p-type semiconductor layer of said one power generating laminate or of the power generating laminate, on the first electrode side, of said plurality of power generating laminates is in contact with said first electrode layer and said n-type semiconductor layer of said one power generating laminate or of the power generating laminate, on the second electrode side, of said plurality of power generating laminates is in contact with said second electrode layer, and
at least a portion, being in contact with said p-type semiconductor layer, of said first electrode layer comprises a metal having a work function which is larger in absolute value than an upper limit energy level of a valence band of said contacting p-type semiconductor layer.

8. A photoelectric conversion element structure according to claim 6, wherein said at least a portion, being in contact with said p-type semiconductor layer, of said first electrode layer is formed of at least one kind of elementary metal selected from the group comprising nickel (Ni), iridium (Ir), palladium (Pd), and platinum (Pt), or an alloy thereof.

9. A photoelectric conversion element structure according to claim 6, wherein said first electrode layer is formed of the metal having the work function which is larger in absolute value than the upper limit energy level of the valence band of said contacting p-type semiconductor layer.

10. A photoelectric conversion element structure according to claim 6, wherein a portion, other than said portion being in contact with said p-type semiconductor layer, of said first electrode layer is formed of a metal with a conductivity higher than that of the metal having the work function which is larger in absolute value than the upper limit energy level of the valence band of said contacting p-type semiconductor layer.

11. A photoelectric conversion element structure comprising an i-type semiconductor layer, a one conductivity-type semiconductor layer formed in contact with one surface of said i-type semiconductor layer, and a metal layer comprising a predetermined metal and formed in direct contact with another surface of said i-type semiconductor layer.

12. A photoelectric conversion element structure according to claim 11, wherein said metal layer, along with said i-type semiconductor layer and said one conductivity-type semiconductor layer, forms a power generating region.

13. A photoelectric conversion element structure according to claim 11, comprising an electrode formed in contact with said one conductivity-type semiconductor layer directly or through another power generating region.

14. A photoelectric conversion element structure according to claim 11, comprising electrode layer formed in contact with said metal layer.

15. A photoelectric conversion element structure according to claim 11, wherein said one conductivity-type semiconductor layer formed in contact with said one surface of said i-type semiconductor layer is a p-type semiconductor layer.

16. A photoelectric conversion element structure according to claim 11, wherein when a semiconductor forming said i-type semiconductor layer is an n-type semiconductor, the metal of said metal layer formed in contact with said another surface of said i-type semiconductor layer is a metal having a work function which is smaller in absolute value than an electron affinity of said n-type semiconductor.

17. A photoelectric conversion element structure according to claim 11, wherein said one conductivity-type semiconductor layer formed in contact with said one surface of said i-type semiconductor layer is an n-type semiconductor layer and, when a semiconductor forming said i-type semiconductor layer is a p-type semiconductor, the metal of said metal layer formed in contact with said another surface of said i-type semiconductor layer is a metal having a work function which is larger in absolute value than an upper limit energy level of a valence band of said p-type semiconductor.

18. A photoelectric conversion element structure comprising a first electrode layer, a second electrode layer, and one or a plurality of power generating laminates provided between said first and second electrode layers,
wherein said power generating laminate comprises a p-type semiconductor layer, an i-type semiconductor layer formed in contact with said p-type semiconductor layer, and an n-type semiconductor layer formed in contact with said i-type semiconductor layer,
said p-type semiconductor layer of said one power generating laminate or of the power generating laminate, on the first electrode side, of said plurality of power generating laminates is in contact with said first electrode layer and said n-type semiconductor layer of said one power generating laminate or of the power generating laminate, on the second electrode side, of said plurality of power generating laminates is in contact with said second electrode layer, and
at least a portion, being in contact with said n-type semiconductor layer, of said second electrode layer comprises a metal having a work function which is smaller in absolute value than those of Al and Ag.

19. A photoelectric conversion element structure according to claim 18, wherein said at least a portion, being in contact with said n-type semiconductor layer, of said second electrode layer is formed of at least one kind of elementary metal selected from the group comprising manganese and zirconium, or an alloy thereof.

20. A photoelectric conversion element structure comprising a first electrode layer, a second electrode layer, and one or a plurality of power generating laminates provided between said first and second electrode layers,
wherein said power generating laminate comprises a p-type semiconductor layer, an i-type semiconductor layer formed in contact with said p-type semiconductor layer, and an n-type semiconductor layer formed in contact with said i-type semiconductor layer,
said p-type semiconductor layer of said one power generating laminate or of the power generating laminate, on the first electrode side, of said plurality of power generating laminates is in contact with said first electrode layer and said n-type semiconductor layer of said one power generating laminate or of the power generating laminate, on the second electrode side, of said plurality of power generating laminates is in contact with said second electrode layer, and
at least a portion, being in contact with said p-type semiconductor layer, of said first electrode layer comprises a metal having a work function which is larger in absolute value than that of ZnO.

21. A photoelectric conversion element structure according to claim 20, wherein said at least a portion, being in contact with said p-type semiconductor layer, of said first electrode layer is formed of cobalt (Co) or an alloy thereof.

22. A photoelectric conversion element structure according to claim 11, characterized in that said i-type semiconductor layer is formed of silicon.

23. A solar cell characterized by comprising the photoelectric conversion element structure according to claim 1.
